(19) United States
(12) Patent Application Publication
(10) Pub. No.: US 2018/0005972 A1
(43) Pub. Date: Jan. 4, 2018

(54) INTERFACE STRUCTURES FOR PACKAGED CIRCUITRY AND METHOD OF PROVIDING SAME

(71) Applicant: Intel Corporation, Santa Clara, CA (US)

(72) Inventors: Md Altaf HOSSAIN, Portland, OR (US); Cliff C. LEE, Portland, OR (US)

(21) Appl. No.: 15/201,332

(22) Filed: Jul. 1, 2016

(51) Int. Cl. H01L 23/00; H01L 23/31; H01L 21/66

(52) U.S. Cl. CPC H01L 24/14; H01L 24/11; H01L 22/26; H01L 23/3114; H01L 24/09

(57) ABSTRACT

Techniques and mechanisms for determining an accessibility of circuit functionality via interface structures of a microelectronic device. In an embodiment, a packaged microelectronic device includes a substrate having interconnect structures formed therein. The interconnect structures variously couple one or more integrated circuit (IC) dies of the packaged microelectronic device to respective conductors (or “contact lands”) at a side of the substrate. Access to some functionality of the one or more IC dies via certain ones the contact lands—the access during an operational mode of the packaged microelectronic device—may be selectively disabled based on testing which evaluates performance characteristics of the packaged microelectronic device. In another embodiment, some of the contact lands are covered with an insulator material to prevent deposition of solder on such contact lands.

### BACKGROUND

### 1. Technical Field

The present disclosure relates generally to the field of microelectronic devices, and more particularly, but not exclusively, to interface hardware of a microelectronic package.

### 2. Background Art

In the production of microelectronic packages, one or more integrated circuit (IC) dies are typically mounted on a microelectronic substrate for packaging purposes. The one or more IC dies usually include a microprocessor, chipset circuitry, graphics processing circuitry, wireless communication circuitry, memory device, application specific integrated circuits or the like. The microelectronic substrate is often an interposer or any of various other substrate types having formed therein vias, traces and/or other interconnect structures that couple the one or more IC dies to conductive contacts of a hardware input/output (I/O) interface.

Manufacturers often design different types of microelectronic devices, each type to accommodate a particular one or more (but not all) of the solutions that a customer is trying to implement. Under existing techniques, such design includes defining a hardware I/O interface specific to a particular one or more IC dies that are to operate with that hardware I/O interface. More specifically, each conductive contact of the hardware I/O interface is designed to provide a respective type of access to circuitry of the microelectronic device during its operation.

Often, a manufacturer provides a microelectronic device supporting functionality that is extraneous to that needed for a particular use case. In some situations, a customer may nevertheless select such a microelectronic device for that use case. Under conventional techniques, such selection often results in a system having I/O interface contacts that provide little or no function to support the use case in question.

### BRIEF DESCRIPTION OF THE DRAWINGS

The various embodiments of the present invention are illustrated by way of example, and not by way of limitation, in the figures of the accompanying drawings and in which:

FIG. 1 is a hybrid perspective view and functional block diagram illustrating elements of a system to configure a microelectronic device according to an embodiment.

FIG. 2 is a flow diagram illustrating elements of a method for configuring a microelectronic device according to an embodiment.

FIGS. 3A, 3B are cross-sectional diagrams of systems including respective interface structures each according to a corresponding embodiment.

FIG. 4 is a plan view showing an interface of a microelectronic device according to an embodiment.

FIGS. 5A and 5B show cross-sectional views of respective packaged microelectronic devices including interface structures each according to a corresponding embodiment.

FIG. 6 shows plan views of respective packaged device interfaces each according to a corresponding embodiment.

FIG. 7 is a functional block diagram illustrating elements of a computing device in accordance with one embodiment.

FIG. 8 is a functional block diagram illustrating elements of an exemplary computer system, in accordance with an embodiment.

### DETAILED DESCRIPTION

Embodiments discussed herein variously provide techniques and mechanisms for determining a configuration of a microelectronic device. In some embodiments, a packaged microelectronic device includes interconnect structures that variously extend each to a respective conductive pad (also referred to herein as a “contact land”) at a side of a substrate. The accessibility of various circuit components' functionality via such conductive pads may be selectively determined based on an evaluation of whether the packaged microelectronic device meets certain performance criteria. For example, such evaluation may determine whether various contact lands are to have solder balls disposed thereon, whether interconnect structures are to be switchedly or otherwise decoupled from respective circuit components and/or whether functionality of circuit components is to be variously disabled. In allowing for any of various configurations of a packaged integrated circuit device during a test/evaluation stage of manufacturing, some embodiments provide for improvements to device cost and/or form factor, as compared to conventional techniques.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. In some embodiments the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices including one or more integrated circuit (IC) dies and contact lands to provide access to the one or more IC dies.

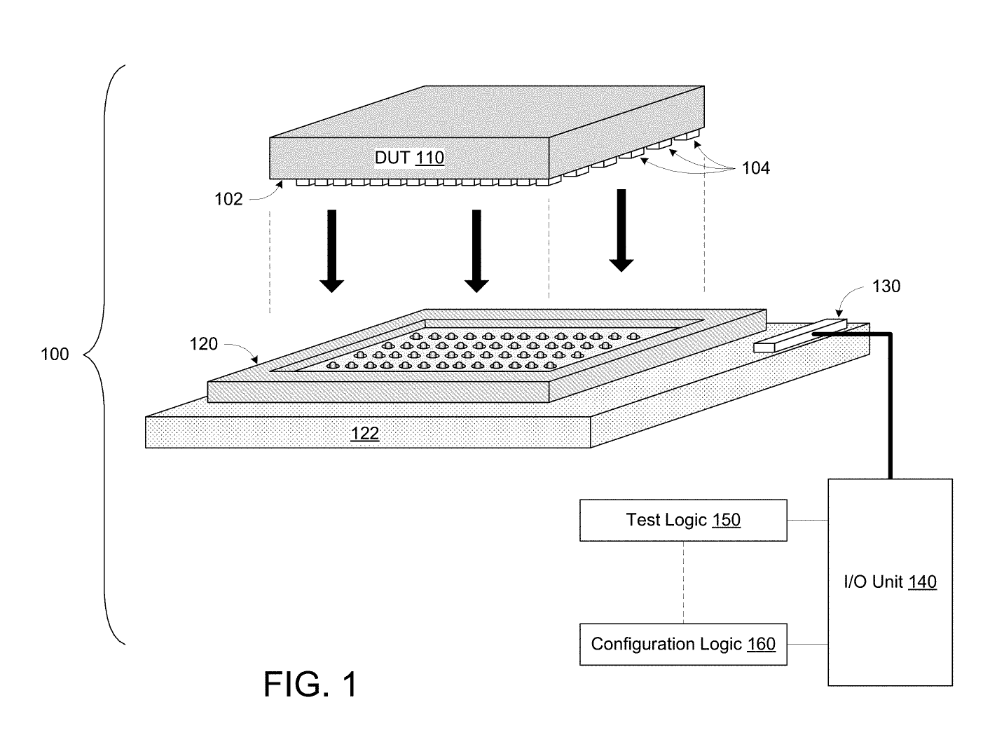

FIG. 1 shows an exploded view of a system 100 to determine functionality that is to be accessible via interconnect structures of a microelectronic device according to an embodiment. A platform 120 of system 100 may provide for testing of the device (for brevity, referred to herein as “device under test” or “DUT”)—e.g., to determine whether circuitry of the device is to be selectively configured and/or whether solder structures (referred to herein as “solder balls”) are to be selectively included as part of the DUT. Such solder structures may facilitate a later coupling of the DUT to a printed circuit board or other electronic device.

In the illustrative embodiment shown, system 100 includes or is to couple to a DUT 110 for evaluation thereof. DUT 110 represents one embodiment of a device that includes one or more integrated circuit (IC) dies, an interposer or other such substrate, and conductive contacts at a side of the substrate. The substrate may comprise one or more layers (e.g., including a core and one or more build up layers) having formed therein interconnect structures each coupled to a respective one of the conductive contacts. Some or all of the interconnect structures may variously extend between opposing sides of the substrate to couple a contact land to a respective circuit component of the one or more IC dies. DUT 110 may include a packaged microelectronic device such as any of a variety of processors, memory packages, controllers, hub devices, system-in-package devices or the like.

In an embodiment, platform 120 includes a test socket or other mounting hardware that provides mechanical support for connecting to DUT 110 via contact lands 104 at a side 102 thereof. A substrate 122 of platform 120 may include a printed circuit board having disposed therein or thereon one or more signal traces, circuit elements and/or other structures that, for example, facilitate signal communication between contact lands 104 and one or more interfaces of platform 120 (such as the illustrative connector 130).

Platform 120 may further include or couple to circuitry that is operable to perform testing of DUT 110 and/or processing of DUT 110 based on such testing. By way of illustration and not limitation, platform 120 may further include or couple to an input/output (TO) unit 140 comprising circuitry to exchange signals with connector 130 on behalf of one or more components, such as the illustrative test logic 150 and/or configuration logic 160 of system 100.

Test logic 150 may include circuitry, stored instructions, executing software and/or other logic to send test signals to DUT 110—e.g., via connector 130, substrate 122 and contact lands 104. In response to such test signals, some or all of contact lands 104 may variously output to platform 120 signals which indicate operational characteristics of DUT 110. Such output signals may be provided to test logic 150 (or other evaluation logic of system 100) that has access to reference information representing performance criteria. Based on such performance criteria and the output signals, operational characteristics of DUT 110 may be evaluated—e.g., by test logic 150—to determine a subsequent processing of DUT 110. By way of illustration and not limitation, test logic 150 may provide to configuration logic 160 signaling which indicates whether (or not) DUT 110 meets operational requirements for DUT 110 to provide a particular level of functionality. In response to such signaling, circuitry, executing software and/or other such resources of configuration logic 160 may provide signals—e.g., via IO unit 140 and connector 130—to control a deposition of solder balls each on a respective one of contact lands 104. Alternatively or in addition, such signals may control the configuring of circuitry in DUT 110. For example, configuration logic 160 may provide control signals to set configuration state of one of more fuses, antifuses, switches and/or other such circuitry of DUT 110.

Platform 120 represents one example of hardware to perform processing which includes communicating test signals with DUT 110, performing an evaluation of performance characteristics and, based on such evaluation, selectively depositing solder balls on DUT 110 and/or configuring circuitry of DUT 110. However, such processing may instead be performed by multiple devices, in another embodiment. For example, multiple devices may be variously coupled to and decoupled from DUT 110, successively, each such device to perform a respective one or more operations of such processing. In an embodiment, DUT 110 may at one point be coupled to a test platform and subsequently—after testing operations are performed—decoupled from the test platform and coupled to another platform that is to selectively deposit a ball grid array and/or configure circuitry of DUT 110 based on a result of such test operations.

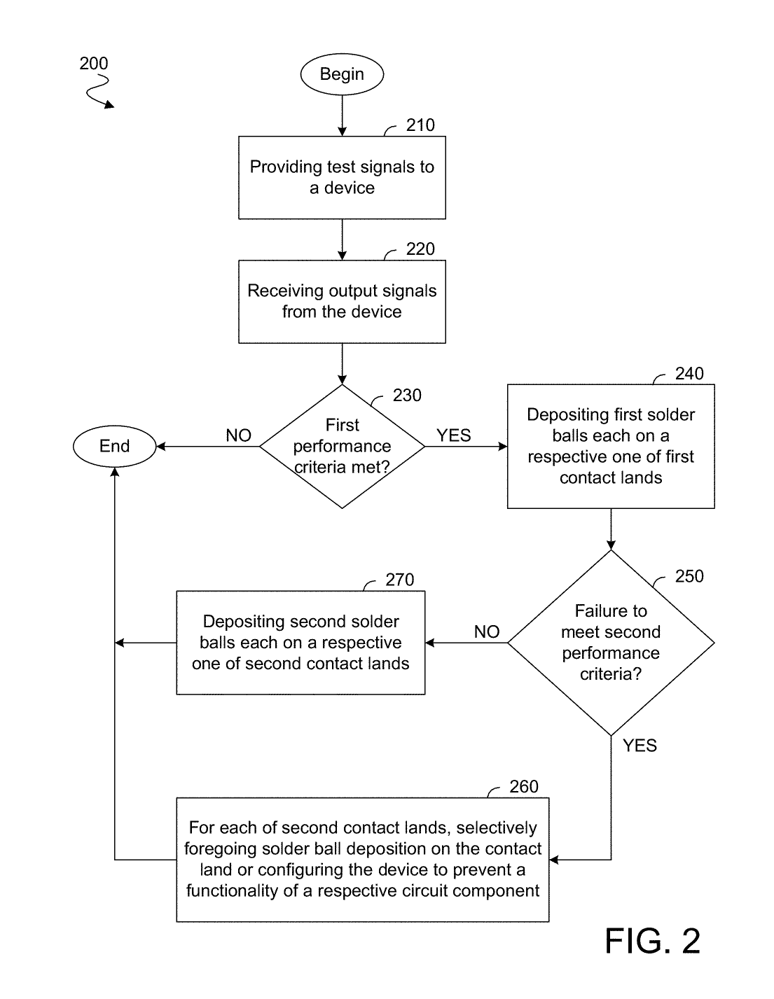

FIG. 2 shows features of a method 200 to determine accessibility to functionality of a microelectronic device according to an embodiment. Method 200 may determine the providing of access to functionality of DUT 110, for example. In an embodiment, hardware and/or software such as that of platform 120 is to perform some or all of method 200.

Method 200 may comprise, at 210, providing test signals to a microelectronic device. The test signals may be sent to detect for connectivity to circuit components of the microelectronic device and/or respective operational characteristics of such circuit components. Method 200 may further comprise, at 220, receiving from the microelectronic device output signals that are based on the test signals. The signaling at 210, 220—performed, for example, with test logic 150—may include communicating any of a variety of signals adapted from conventional techniques for fault detection and/or other evaluation of integrated circuitry.

Based on the output signals received at 220, method 200 may determine, at 230, whether the microelectronic device meets first performance criteria. The determining at 230 may include an evaluation of operational characteristics of the microelectronic device to determine, for example, whether one or more circuit components have been decoupled or otherwise damaged as a result of stresses during processing (e.g., molding, curing, etc.) to package one or more IC dies of the device. The first performance criteria may correspond to a first set of functionalities that the microelectronic device is under consideration as potentially supporting. For example, the first performance criteria may include reference information—e.g., provided a priori—describing circuit connectivity, timing tolerances, response times, signal rise times, signal fall times, signal integrity, power efficiency and/or other threshold operational characteristics that might be required to provide the first set of functionalities. Although some embodiments are not limited in this regard, method 200 may end—or, in other embodiments, perform one or more diagnostic and/or remedial operations (not shown)—where it is determined at 230 that the microelectronic device does not meet the first performance criteria.

Where it is instead determined at 230 that the microelectronic device does meet the first performance criteria, method 200 may, at 240, deposit first solder balls each on a respective one of first contact lands of the microelectronic device. The first contact lands may be less than all contact lands of the microelectronic device—e.g., where method 200 may further determine whether or not second contact lands of the device are to have solder balls variously disposed thereon. For example, method 200 may further comprise detecting, at 250, for a failure of the microelectronic device to meet a second performance criteria. The detecting at 250 may include evaluating that is similar in various respects to that of the determining at 230—e.g., wherein the second performance criteria instead represents a second set of functionalities (e.g., instead of or in addition to the first set of functionalities) that the microelectronic device is under consideration as potentially supporting.

Where the failure is detected at 250, then method 200 may perform processing to variously restrict access to functionality via second contact lands of the microelectronics device. As illustrated at 260, such processing may include, for each contact land of second contact lands, selectively foregoing a deposition of a solder ball on the each contact land, or configuring the microelectronic device to prevent a functionality of a respective circuit component. But for the preventing, such functionality would, during an operational mode of the device, be based on or enable a communication of a signal or a voltage between the particular one of the second contact lands and the respective circuit component. The processing represented at 260 may include preventing an accessibility to circuit functionality that might otherwise be provided if the failure is not detected at 250. For example, although some embodiments are not limited in this regard, method 200 may further comprise depositing second solder balls, at 270, each on a respective one of the second contact lands, where the failure is not detected at 250.

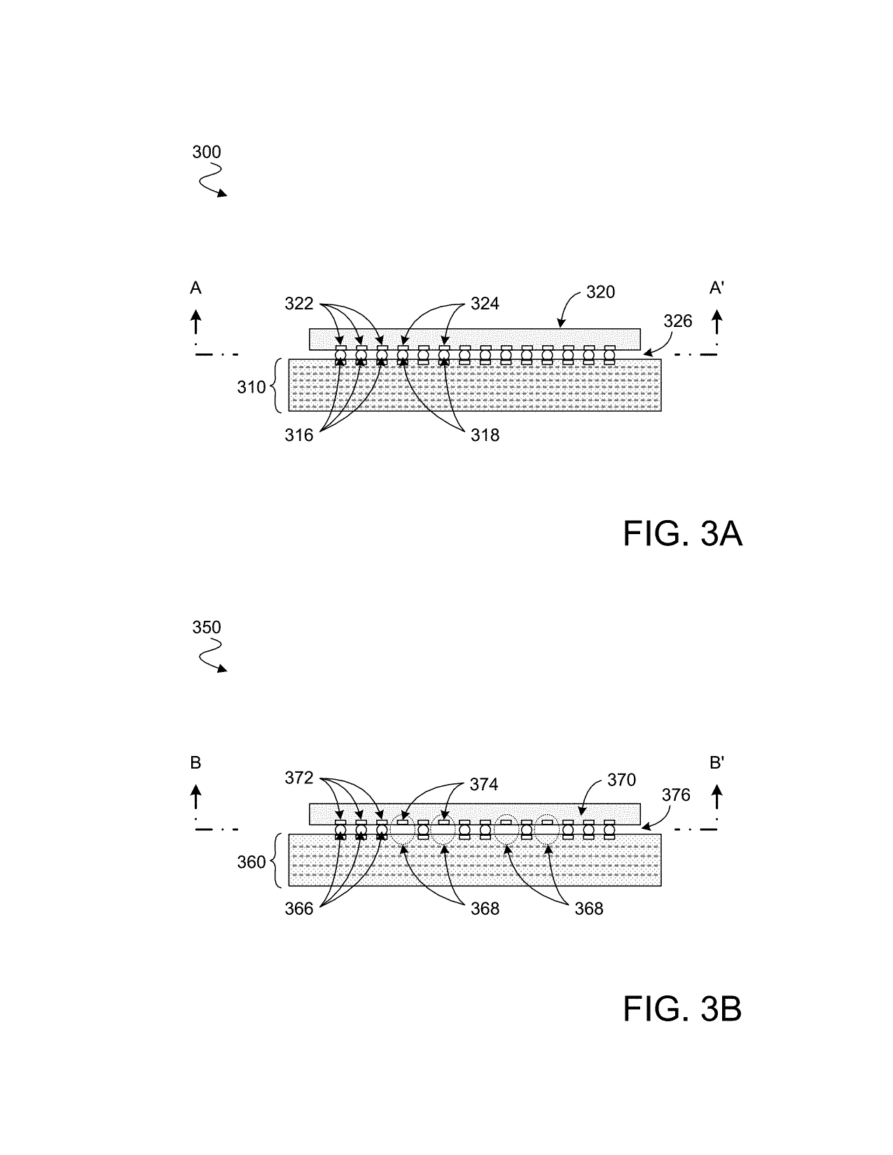

FIG. 3A illustrates a cross-sectional side view of a system 300 according to one embodiment. System 300 comprises a printed circuit board 310 and a packaged microelectronic device 320 coupled thereto. Packaged microelectronic device 320 may include some or all features of DUT 110, for example. Operation of packaged microelectronic device 320 as a component of system 100 may be based on earlier testing to evaluate whether circuitry of packaged microelectronic device 320 is to support a particular set of functionalities (e.g., as opposed to supporting merely a subset of such functionalities and/or an alternative set of functionalities).

In the illustrative embodiment shown, a hardware interface 326 of system 300 includes solder joints that variously couple conductive pads at a side of printed circuit board 310 each to a respective contact land of packaged microelectronic device 320. By way of illustration and not limitation, solder joints 316 may couple first pads each to a respective one of first contact lands 322, where solder joints 318 couple other pads each to a respective one of second contact lands 324. Some or all such solder joints may be formed from previous solder balls of packaged microelectronic device 320. An earlier testing of packaged microelectronic device 320—e.g., performed by system 100 and/or according to method 200—may have determined processing to selectively deposit such solder balls. Alternatively or in addition, such processing may selective decouple, disable or other limit access to functionality of packaged microelectronic device 320.

In the example embodiment of system 300, each of the contact lands shown is soldered to a respective pad of printed circuit board 310. However, a system according to another embodiment may provide a different configuration of a packaged microelectronic device—e.g., for a different interface between the packaged microelectronic device and a printed circuit board. Such different configuration may be based on testing which determines that performance characteristics of packaged microelectronic device 320 instead supports a different (e.g., only a relatively smaller) set of functionalities.

For example, FIG. 3B shows a cross-sectional side view of a system 350 according to another embodiment. System 350 includes a printed circuit board 360 and a packaged microelectronic device 370 coupled thereto via a hardware interface 376—e.g., wherein at least some integrated circuitry and interconnect structures of packaged microelectronic device 370 correspond functionally to respective circuitry and interconnect structures of packaged microelectronic device 320.

Solder joints 366 of hardware interface 376 may couple first pads of printed circuit board 360 each to a respective one of first contact lands 372 (which, for example, corresponding functionally to first contact lands 322). Some or all such solder joints may be formed from previous solder balls of packaged microelectronic device 370—e.g., wherein an earlier deposition of such solder balls (and/or other processing of packaged microelectronic device 370) is selectively performed according to method 200.

As compared to hardware interface 326, hardware interface 376 may be a relatively low density interconnect for coupling a packaged microelectronic device to a printed circuit board. For example, hardware interface 376 may include one or more regions, such as the illustrative regions 368, in which are located contact lands of packaged microelectronic device 370 other than any contact land having solder directly disposed thereon. Such contact lands in regions 368 may include the illustrative contact lands 374 that, for example, correspond to contact lands 324. Although some embodiments are not limited in this regard, some or all of contact lands 374 may be covered by a mold material or other insulator to prevent direct coupling of such contact lands to other circuitry external to microelectronic device 370. In some embodiments, some or all of contact lands 374 are additionally or alternatively decoupled from respective circuit components of microelectronic device 370, and/or some or all such circuit components are configured to prevent operational functionality based on communication with contact lands 374.

A selective preventing of access to at least some functionality of microelectronic device 370 via certain contact lands (such as contact lands 374) may be based on earlier testing—e.g., according to method 200—which detects a failure of microelectronic device 370 to meet one or more performance criteria associated with such functionality. For example, solder joints 318 may be formed from solder balls that are deposited at operation 270 of method 200 in one embodiment. By contrast, access to functionality of microelectronic device 370 via contact lands 374 may be prevented by the processes at operation 260 of method 200 in another embodiment.

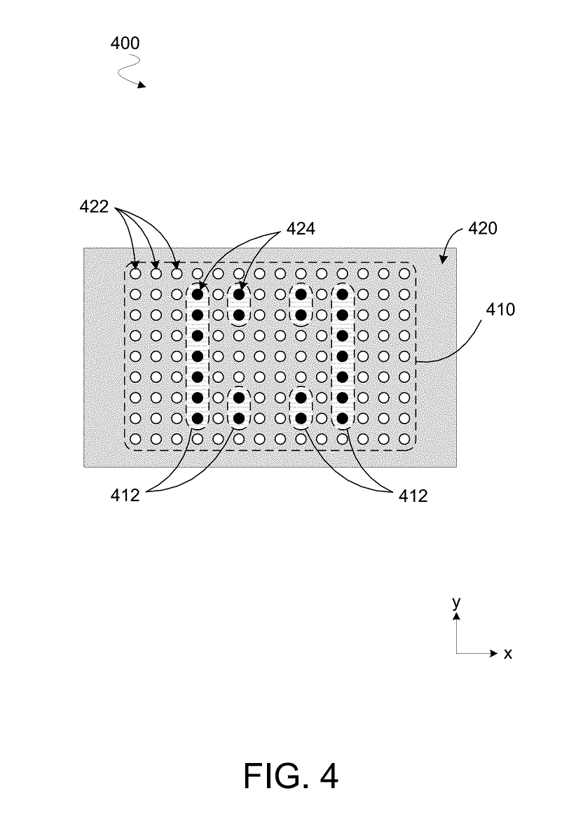

FIG. 4 shows a bottom plan view of a microelectronic device 400 which, according to one embodiment, comprises a configuration of contact lands adaptable to accommodate any of different sets of functionalities to be provided by microelectronic device 400. The arrangement of contact lands shown in bottom plan view 400 may reside in the cross-sectional plane A-A′ shown for microelectronic device 320. Alternatively, such an arrangement of contact lands may reside in the cross-sectional plane B-B′ shown for microelectronic device 370.

Solder balls or solder joints (not shown) may be variously disposed each on a respective one of the contact lands of microelectronic device 400. Alternatively or in addition, selected ones of the contact lands of microelectronic device 400—e.g., only a subset of all contact lands—may provide access to respective functionality of microelectronic device 400 during an operation mode thereof. An arrangement of solder balls (or solder joints) and/or accessibility to functionality of microelectronic device 400 via contact lands may be based on testing—e.g., according to method 200—which determines whether operational characteristics of microelectronic device 400 satisfy particular test criteria.

As shown in FIG. 4, a side 420 of the microelectronic device 400 may include a plurality of contact lands, shown as including the illustrative contact lands 422, 424. The contact lands 422 (i.e., unshaded) represent connections utilized to access a first set of functionalities that may be provided, for example, by microelectronic device 370. The contact lands 424, which are shaded for clarity, may be specific to a second set of functionalities that, of microelectronic devices 320, 370, may be provided only by microelectronic device 320. Contact lands 424 may include a contiguous group of contact lands, where “contiguous” in this context refers to the characteristic of contact lands (of a common type) being the closest contact lands to each other along a line of direction extending therebetween. A group of contact lands is contiguous where each contact land of the group is contiguous with at least one other contact land of the group. Although some embodiments are not limited in this regard, such a contiguous group may include three or more contiguous contact lands that (similar to some of contact lands 422, for example) are arranged in line with one another along one of the x-axis and y-axis shown. Such a contiguous group may be variously confined along the x-axis and/or along the y-axis by various ones of contact lands 424.

Contact lands 422 and 424 may be located in a connection zone 410 of side 420, and accommodate coupling to respective solder joints of hardware interface 326. In another embodiment, a subset of zone 410—e.g., the subset including one or more constituent sub-zones 412—may include contact lands 424 that, for example, are contact lands other than any that are directly soldered to form hardware interface 376.

In one embodiment, microelectronic device 370 may be viewed as a “base package”, which supports a relatively more limited set of functionalities—e.g., as compared to that provided with microelectronic device 320. Microelectronic device 400 may be configured to operate as microelectronic device 370 by providing this relatively limited set of functionalities—e.g., wherein contact lands 422 (but not contact lands 424) are to variously provide access to such a limited set. In such an embodiment, one or more hardwired and/or switched configurations of microelectronic device 400 may additionally or alternatively prevent some or all of contact lands 424 from providing access to respective functionality during an operational mode of microelectronic device 400.

The microelectronic device 320 may be viewed as a “superset package” which supports a relatively large set of functionalities. In such an embodiment, microelectronic device 400 may instead be configured to operate as microelectronic device 320—e.g., wherein both contact lands 422 and contact lands 424 are to variously provide access to a relatively large set of functionalities. The location and the count of the common contact lands 422 may not change between a “base package” configuration of microelectronic device 400 (e.g. corresponding to microelectronic device 370) and the “superset package” of microelectronic device 400 (e.g. corresponding to microelectronic device 320). Therefore, the arrangement of contact lands in zone 410 may be designed based on a “superset package” form factor, such that the microelectronic device 400 arrangement may be configured to accommodate either a “base package” functionality (e.g. for microelectronic device 370) or a “superset package” functionality (e.g. microelectronic device 320). Thus, some embodiments variously enable selection between either of two different interface form factors—e.g., where selection of one such form factor depends on whether (or not) operational characteristics of microelectronic device 400 can accommodate “superset package” functionality or merely “base package” functionality.

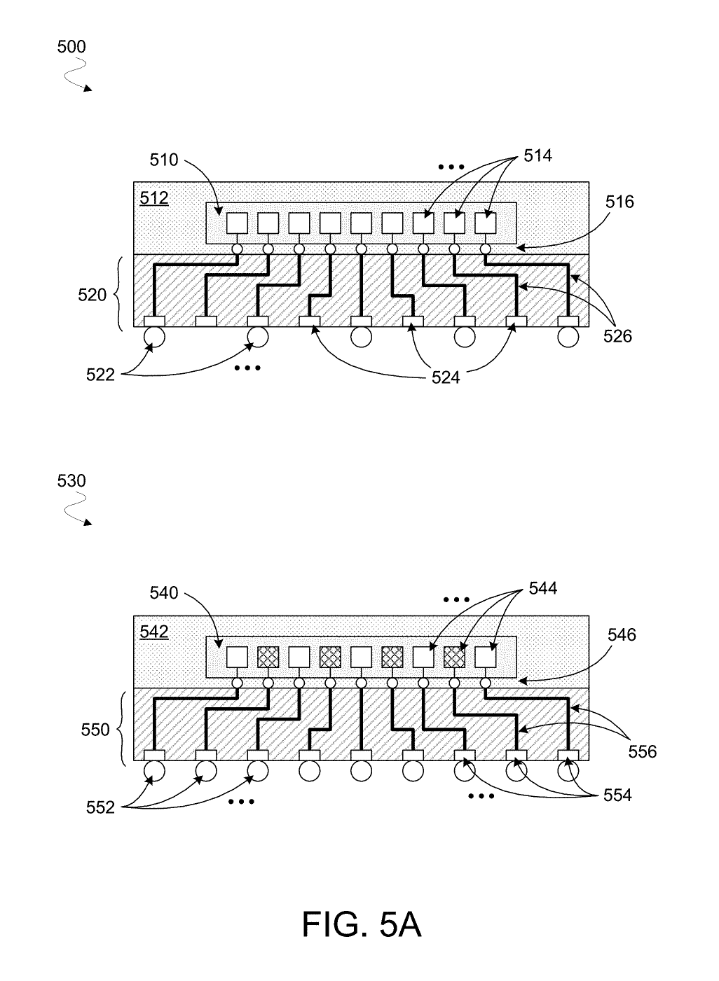

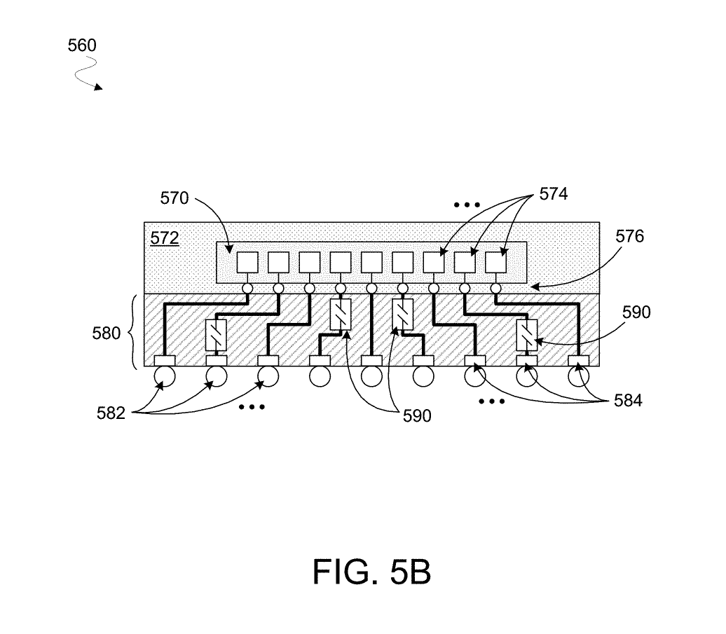

FIG. 5A shows features of a packaged microelectronic device 500 according to one embodiment. Microelectronic device 500 may include some or all of the features of DUT 110, microelectronic device 370 or microelectronic device 400, for example. Access to some functionality of packaged microelectronic device 500 may be prevented (or alternatively facilitated) by circuit configuration and/or interconnect structures that are determined according to method 200.

In the illustrative embodiment shown, packaged microelectronic device 500 includes a substrate 520 and one or more IC dies disposed thereon (such as the illustrative IC die 510 shown). Substrate 520 may comprise any of a variety of one or more insulator layers having conductive interconnects 526 variously formed therein—e.g., wherein substrate 520 includes an interposer. A package mold 512 (such as a plastic or epoxy resin) may be disposed around IC die 510, although some embodiments are not limited in this regard.

In an embodiment, contact lands are disposed at a first (bottom) side of substrate 520, wherein interconnects 526 variously provide connectivity between respective ones of contact lands and a second side of substrate 520 (opposite the first side). For example, IC die 512 may include various circuit components 514 and contacts 516 each coupled to a respective one of circuit components 514. Contacts 516 may include controlled collapsed chip connection (C4) bumps, in one embodiment.

Each of circuit components 514 may be selectively coupled to support communication of a respective signal or voltage with a corresponding contact land (or, in some embodiments, to perform one or more operations based on such a signal or voltage). Such coupling may be contingent upon the formation of a solder joint from a solder ball deposited on the corresponding contact land. For example, an arrangement of solder balls may facilitate a later access, during an operation mode of packaged microelectronic device 500, to certain functionality of IC die 510 via some contact lands. In some embodiments, access to the respective functionality of only some of circuit components 514 may be supported via contact lands. For example, packaged microelectronic device 500 may include solder balls 522 that are deposited on only some contact lands, where packaged microelectronic device 500 also includes contact lands 524 other than any contact lands having solder disposed thereon.

Selective deposition of solder balls on only some contact lands of packaged microelectronic device 500 (but not contact lands 524, for example) may prohibit or otherwise limit adaptation of packaged microelectronic device 500 for use in a relatively high functionality (“superset”) use case. Instead, packaged microelectronic device 500 may be more readily adaptable for use in a lower functionality (“base”) use case. In some embodiments, some or all of contact lands 524 are variously covered with an epoxy or other insulator material (not shown) that prevents deposition of solder thereon.

FIG. 5A also shows features of a packaged microelectronic device 530 according to another embodiment. Microelectronic device 530 may include some or all of the features of DUT 110, microelectronic device 370 or microelectronic device 400—e.g., wherein access to functionality of packaged microelectronic device 530 is selectively prevented by circuit configuration and/or interconnect structures determined according to method 200. Packaged microelectronic device 530 may include a substrate 550 and an IC die 540 disposed thereon (e.g., wherein a package mold 542 is disposed on IC die 540). IC die 540 may include circuit components 544 that, for example, correspond functionally to circuit components 514. Conductive interconnects 556 formed in substrate 550 may variously couple contact lands 554 (at a bottom side of substrate 550) each to a respective one of circuit components 544—e.g., via C4 bumps 546. In the example embodiment of microelectronic device 530, select ones of circuit components 554 (shaded for clarity) are variously switched, fused or otherwise configured to prevent a functionality that would otherwise be accessible via a corresponding one of contact lands 554 during an operational mode of microelectronic device 530. Such access may be prevented regardless of a particular configuration of solder balls 552. Whereas microelectronic device 500 prevents access to circuit functionality by a particular arrangement of solder balls, microelectronic device 530 instead prevents such access by selectively setting disabling modes of various one of the circuit components 554. Some embodiments may include a combination of these various mechanisms to selectively prevent access to functionality of packaged microelectronic device 530.

FIG. 5B shows features of a packaged microelectronic device 560 according to another embodiment. Microelectronic device 560 may include one or more the features of one of packaged microelectronic devices 500, 530. For example, packaged microelectronic device 560 may include a substrate 580 and an IC die 570 disposed thereon (e.g., wherein a package mold 572 is disposed on IC die 570). IC die 570 may include circuit components 574 that, for example, correspond functionally to circuit components 514. Conductive interconnects formed in substrate 580 may variously couple contact lands 584 (at a bottom side of substrate 580) each to a respective one of circuit components 574—e.g., via C4 bumps 576. In the example embodiment of microelectronic device 560, some of the interconnects include fuses 590 that are operable each to selectively disable communication between a respective one of contact lands 584 and a corresponding one of circuit components 574. Accordingly access to some circuit functionality may be selectively prevented—e.g., regardless of a particular configuration of solder balls 582. Some embodiments may include one or more such fuses—e.g., in combination with one or more mechanisms of packaged microelectronic device 500, 530—to selectively prevent access to functionality of packaged microelectronic device 560.

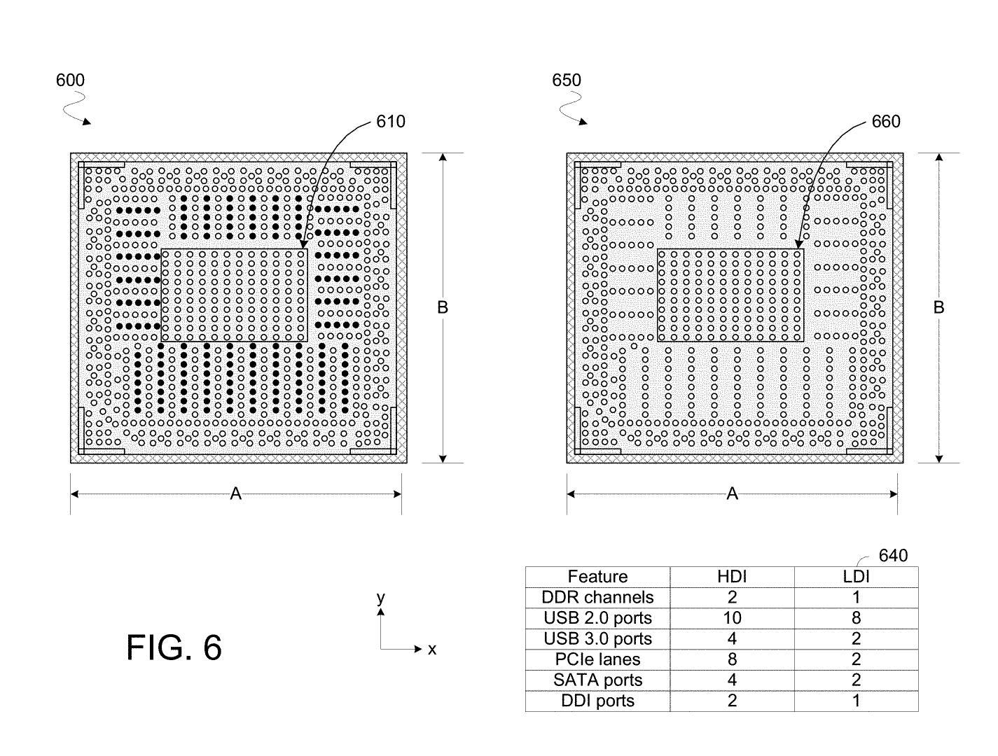

FIG. 6 shows respective configurations of devices 600, 650 each according to a corresponding embodiment. In an embodiment, devices 600, 650 variously include one or more features of DUT 110 and/or may be a result of processing according to method 200. For example, an evaluation of a packaged microelectronic device may determine, at least in part, interconnect structures and/or other configurations of that packaged microelectronic device. Such interconnect structures and/or other configurations may be those of device 600—or, alternatively, of device 650—depending on a result of such evaluation.

In the illustrative embodiment of device 600, contact lands are disposed in a zone having a length A and a width B (in the x, y coordinate system shown). Similarly, respective contact lands of device 650 may be disposed in another zone also having an area of A×B—e.g., wherein devices 600, 650 have respective configurations of at least some contact lands that are congruent with one another. The particular numbers and arrangements of contact lands for devices 600, 650 are merely illustrative, and not limiting on some embodiments. Although thickness (z-height) is not shown in FIG. 6, the respective thicknesses of devices 600, 650, may be the same—or alternatively, different—in some embodiments.

First contact lands, which are shown in FIG. 6 as unshaded, represent connections that are available to provide access to a “base” set of functionalities. For example, devices 600, 650 may both provide the same arrangement of such first contact lands—e.g., where each of devices 600, 650 is to provide at least some first set of functionalities via their respective first contact lands. Although some embodiments are not limited in this regard, some of the first contact lands of device 600 may be disposed in an area 610 directly under one or more IC dies of device 600—e.g., where others of the first contact lands are variously located in a breakout region around area 610. Some of the first contact lands of device 650 may be similarly arranged in an area 660 corresponding to area 610.

By contrast, second contact lands, which are shown in FIG. 6 as shaded, may be specific to a second set of functionalities that, of microelectronic devices 600, 650, may be provided only by microelectronic device 600. As illustrated by microelectronic device 650, the first contact lands and second contact lands may form respective groups (e.g., including respective lines) of contiguous contact lands, where such groups are interleaved or otherwise alternating with each other. However, any of a variety of additional or alternative arrangements of the first contact lands and second contact lands may be variously provided, in different embodiments.

The second contact lands of microelectronic device 650 may provide access to functionality which is supplemental to that provided by the first contact lands of microelectronic device 650 (e.g., and, in another embodiment, by the first contact lands of microelectronic device 600). By way of illustration and not limitation, second contacts lands may provide access to circuitry that supports one or more input/output paths—e.g., including any of a variety of one or more ports, channels, lanes and/or the like—according to a communication standard. Table 640 shows some examples of differences, in various embodiments, between a relatively high density interconnect (HDI) such as that supported by device 600 and a relatively low density interconnect (LDI) such as that supported by device 650. As shown in table 640, a LDI may support only one dual data rate (DDR) memory channel, where a corresponding HDI (having an arrangement of some contact lands which is congruent to that of the LDI) may supplement one additional DDR channel.

Alternatively or in addition, such an HDI and LDI may variously provide different respective numbers of Universal Serial Bus (USB) 2.0 ports, USB 3.0 ports, Peripheral Component Interconnect Express (PCIe) lanes, Serial AT Attachment (SATA) ports, digital display interface (DDI) ports and/or the like. The particular types and number of I/O resources variously provided by the HDI and LDI is merely illustrative and not limiting on some embodiments. Selective configuration of a microelectronic device to provide a particular one of the HDI and LDI (rather than the other of the HDI and LDI) may depend on testing—e.g., according to method 200—to evaluate performance characteristics of the microelectronic device.

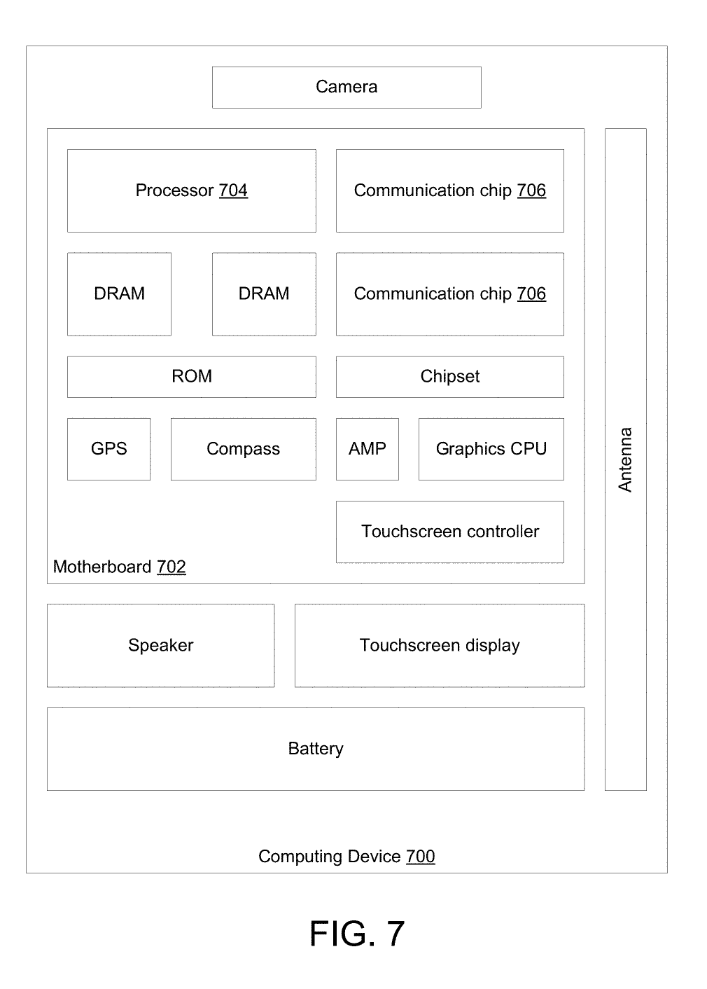

FIG. 7 illustrates a computing device 700 in accordance with one embodiment. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. The term “processor” may refer to any device or portion of a device that processes electronic data from registers and/or memory to transform that electronic data into other electronic data that may be stored in registers and/or memory. The communication chip 706 also includes an integrated circuit die packaged within the communication chip 706.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

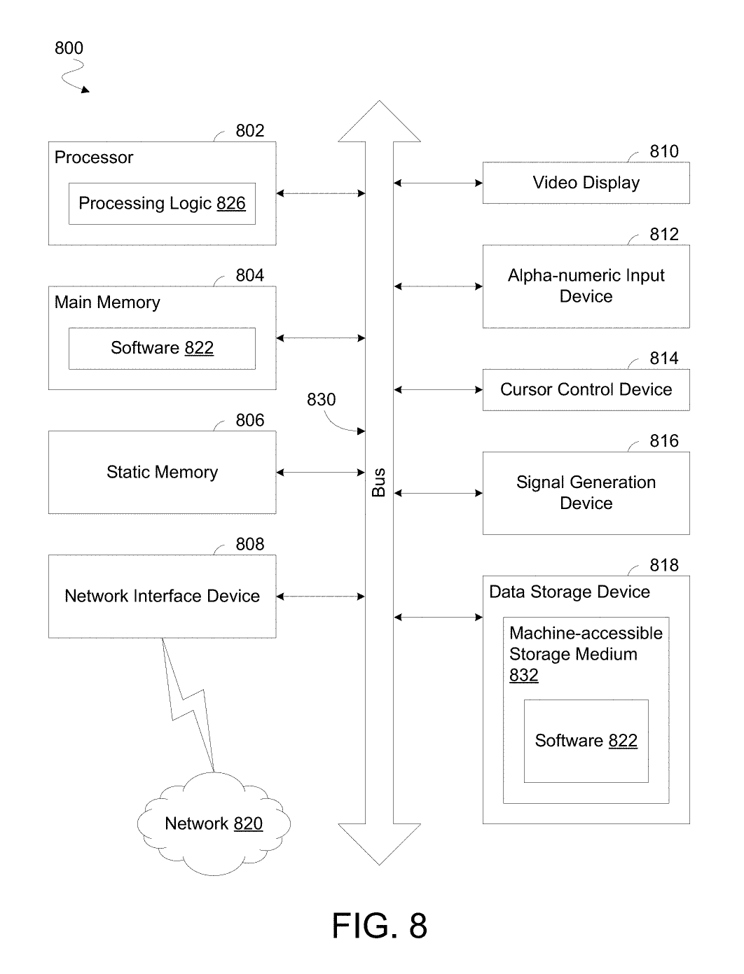

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 832 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, a microelectronic device comprises a substrate including a first side and a second side, contact lands disposed at the first side, the contact lands including first contact lands and second contact lands, one or more integrated circuit (IC) dies coupled to the substrate via the second side, wherein each of the contact lands is coupled to a respective interconnect structure extending at least partially through the substrate, and a package mold disposed on the second side and the one or more IC dies. Solder balls are each disposed on a respective one of the second contact lands, wherein, for each contact land of the first contact lands any solder ball of the device is disposed on a contact land other than the each contact land, or a hardwired or switched configuration of the device prevents a respective functionality of the circuit component that, during an operational mode of the device, is to be based on or is to enable a communication of a signal or a voltage between the each contact land and the respective circuit component.

In one embodiment, of the first contact lands and the second contact lands, only the second contact lands have respective solder balls disposed thereon. In another embodiment, respective surfaces of one or more of the first contact lands each have an insulator material disposed thereon, wherein the insulator material prevents deposition of solder on one or more of the first contact lands. In another embodiment, the substrate has disposed therein or thereon a fuse coupled to one of the first contact lands, wherein the fuse is configured to disable communication between the one of the first contact lands and the one or more IC dies. In another embodiment, the one or more IC dies include a first circuit component coupled to one of the first contact lands, wherein the first circuit component is configured to disable a first functionality of the first circuit component during an operational mode of the microelectronic device. In another embodiment, the first functionality is to support signaling according to a communication standard. In another embodiment, the first contact lands includes a contiguous group of contact lands. In another embodiment, the contiguous group includes three or more contact lands arranged in a line with each other.

In another implementation, a method comprises providing test signals to a packaged microelectronic device including first contact lands and second contact lands, receiving from the packaged microelectronic device output signals based on the test signals, and based on the output signals, determining whether the packaged microelectronic device meets a first performance criteria, and detecting for a failure of the packaged microelectronic device to meet a second performance criteria. The method further comprises, where it is determined that the packaged microelectronic device meets the first test criteria, depositing first solder balls each on a respective one of the first contact lands, and where the failure is detected, for each contact land of the second contact lands, selectively foregoing a deposition of a solder ball on the each contact land, or configuring the packaged microelectronic device to prevent a functionality of a respective circuit component that, during an operational mode of the device, is to be based on or is to enable a communication of a signal or a voltage between the each contact land and the respective circuit component.

In one embodiment, of the first contact lands and the second contact lands, only the first contact lands have respective solder balls disposed thereon. In another embodiment, where the failure is detected, an insulator material is deposited on respective surfaces of one or more of the second contact lands. In another embodiment, a substrate of the packaged microelectronic device has disposed therein or thereon a fuse coupled to one of the second contact lands, wherein, where the failure is detected, the fuse is configured to disable communication between the one of the second contact lands and one or more integrated circuit (IC) dies of the packaged microelectronic device. In another embodiment, one or more integrated circuit (IC) dies of the packaged microelectronic device include a first circuit component coupled to one of the second contact lands, wherein, where the failure is detected, the first circuit component is configured to disable a first functionality of the first circuit component during an operational mode of the microelectronic device. In another embodiment, the first functionality is to support signaling according to a communication standard. In another embodiment, the second contact lands includes a contiguous group of contact lands. In another embodiment, the contiguous group includes three or more contact lands arranged in a line with each other.

In another implementation, a system comprises a printed circuit board and a microelectronic device coupled to the printed circuit board. The microelectronic device includes a substrate including a first side and a second side, contact lands disposed at the first side, the contact lands including first contact lands and second contact lands, one or more IC dies coupled to the substrate via the second side, wherein each of the contact lands is coupled to a respective interconnect structure extending at least partially through the substrate, and a package mold disposed on the second side and the one or more IC dies. Solder balls are each disposed on a respective one of the second contact lands, wherein, for each contact land of the first contact lands, any solder ball of the device is disposed on a contact land other than the each contact land, or a hardwired or switched configuration of the device prevents a respective functionality of the circuit component that, during an operational mode of the device, is to be based on or is to enable a communication of a signal or a voltage between the each contact land and the respective circuit component.

In one embodiment, of the first contact lands and the second contact lands, only the second contact lands have respective solder balls disposed thereon. In another embodiment, respective surfaces of one or more of the first contact lands each have an insulator material disposed thereon, wherein the insulator material prevents deposition of solder on one or more of the first contact lands. In another embodiment, the substrate has disposed therein or thereon a fuse coupled to one of the first contact lands, wherein the fuse is configured to disable communication between the one of the first contact lands and the one or more IC dies. In another embodiment, the one or more IC dies include a first circuit component coupled to one of the first contact lands, wherein the first circuit component is configured to disable a first functionality of the first circuit component during an operational mode of the microelectronic device. In another embodiment, the first functionality is to support signaling according to a communication standard. In another embodiment, the first contact lands includes a contiguous group of contact lands. In another embodiment, the contiguous group includes three or more contact lands arranged in a line with each other.

In another implementation, a non-transitory computer-readable storage medium having stored thereon instructions which, when executed by one or more processing units, cause the one or more processing units to perform a method comprising providing test signals to a packaged microelectronic device including first contact lands and second contact lands, receiving from the packaged microelectronic device output signals based on the test signals, and based on the output signals, determining whether the packaged microelectronic device meets a first performance criteria, and detecting for a failure of the packaged microelectronic device to meet a second performance criteria. The method further comprises, where it is determined that the packaged microelectronic device meets the first test criteria, depositing first solder balls each on a respective one of the first contact lands, and where the failure is detected, for each contact land of the second contact lands, selectively foregoing a deposition of a solder ball on the each contact land, or configuring the packaged microelectronic device to prevent a functionality of a respective circuit component that, during an operational mode of the device, is to be based on or is to enable a communication of a signal or a voltage between the each contact land and the respective circuit component.

In one embodiment, of the first contact lands and the second contact lands, only the first contact lands have respective solder balls disposed thereon. In another embodiment, where the failure is detected, an insulator material is deposited on respective surfaces of one or more of the second contact lands. In another embodiment, a substrate of the packaged microelectronic device has disposed therein or thereon a fuse coupled to one of the second contact lands, wherein, where the failure is detected, the fuse is configured to disable communication between the one of the second contact lands and one or more integrated circuit (IC) dies of the packaged microelectronic device. In another embodiment, one or more integrated circuit (IC) dies of the packaged microelectronic device include a first circuit component coupled to one of the second contact lands, wherein, where the failure is detected, the first circuit component is configured to disable a first functionality of the first circuit component during an operational mode of the microelectronic device. In another embodiment, the first functionality is to support signaling according to a communication standard. In another embodiment, the second contact lands includes a contiguous group of contact lands. In another embodiment, the contiguous group includes three or more contact lands arranged in a line with each other.

Techniques and architectures for providing connectivity with packaged circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1. A microelectronic device comprising:
a substrate including a first side and a second side;
contact lands disposed at the first side, the contact lands including first contact lands and second contact lands;
one or more integrated circuit (IC) dies coupled to the substrate via the second side, wherein each of the contact lands is coupled to a respective interconnect structure extending at least partially through the substrate;
a package mold disposed on the second side and the one or more IC dies;
solder balls each disposed on a respective one of the second contact lands, wherein, for each contact land of the first contact lands:
any solder ball of the device is disposed on a contact land other than the each contact land to prevent a respective functionality of a circuit component.

2. The microelectronic device of claim 1, wherein, of the first contact lands and the second contact lands, only the second contact lands have respective solder balls disposed thereon.

3. The microelectronic device of claim 2, wherein respective surfaces of one or more of the first contact lands each have an insulator material disposed thereon, wherein the insulator material prevents deposition of solder on one or more of the first contact lands.

4. The microelectronic device of claim 1, the substrate having disposed therein or thereon a fuse coupled to one of the first contact lands, wherein the fuse is configured to disable communication between the one of the first contact lands and the one or more IC dies.

5. The microelectronic device of claim 1, the one or more IC dies including a second circuit component coupled to one of the first contact lands, wherein the second circuit component is configured to disable a second functionality of the second circuit component during an operational mode of the microelectronic device.

6. The microelectronic device of claim 5, wherein the first functionality is to support signaling according to a long term evolution (LTE) communication standard.

7. The microelectronic device of claim 1, wherein the first contact lands includes a contiguous group of contact lands.

8. The microelectronic device of claim 7, wherein the contiguous group includes three or more contact lands arranged in a line with each other.

9.-16. (canceled)

17. A system comprising:
a printed circuit board;
a microelectronic device coupled to the printed circuit board, the microelectronic device including:
a substrate including a first side and a second side;
contact lands disposed at the first side, the contact lands including first contact lands and second contact lands;
one or more IC dies coupled to the substrate via the second side, wherein each of the contact lands is coupled to a respective interconnect structure extending at least partially through the substrate;
a package mold disposed on the second side and the one or more IC dies;
solder balls each disposed on a respective one of the second contact lands, wherein, for each contact land of the first contact lands:
any solder ball of the device is disposed on a contact land other than the each contact land to prevent a respective functionality of a circuit component.

18. The system of claim 17, wherein, of the first contact lands and the second contact lands, only the second contact lands have respective solder balls disposed thereon.

19. The system of claim 18, wherein respective surfaces of one or more of the first contact lands each have an insulator material disposed thereon, wherein the insulator material prevents deposition of solder on one or more of the first contact lands.

20. The system of claim 17, the one or more IC dies including a second circuit component coupled to one of the first contact lands, wherein the second circuit component is configured to disable a first functionality of the second circuit component during an operational mode of the microelectronic device.
